(19) United States
(12) Patent Application Publication
(10) Pub. No.: US 2026/0182330 A1
(43) Pub. Date: Jun. 25, 2026

(54) SEMICONDUCTOR DEVICE, MANUFACTURING METHOD, AND ELECTRONIC APPARATUS

(71) Applicant: SONY SEMICONDUCTOR SOLUTIONS CORPORATION, KANAGAWA (JP)

(72) Inventors: KENGO KOTOO, KANAGAWA (JP); YUKARI TAKEYA, KANAGAWA (JP); AKIHISA SAKAMOTO, KANAGAWA (JP)

(21) Appl. No.: 19/129,898

(22) PCT Filed: Nov. 20, 2023
(86) PCT No.: PCT/JP2023/041572

§ 371 Date: May 14, 2025

(30) Foreign Application Priority Data
Nov. 22, 2022 (JP) 2022-186238

(51) Int. Cl. H10W 20/20

(52) U.S. Cl. CPC H10W 20/20

(57) ABSTRACT

The present disclosure relates to a semiconductor device, a manufacturing method, and an electronic apparatus in which the quality can be improved.

The semiconductor device includes a first semiconductor chip, a second semiconductor chip that is bonded to the first semiconductor chip by Cow bonding, and a high-stress film that generates stress to cancel stress to be generated in the first semiconductor chip or the second semiconductor chip during Cow bonding. The high-stress film is disposed in an arrangement pattern having high density in regions close to four corners of the first semiconductor chip or the second semiconductor chip and having low density in a region around the center of the first semiconductor chip or the second semiconductor chip. The present technology is applicable to a lamination-type CMOS image sensor, for example.

### TECHNICAL FIELD

The present disclosure relates to a semiconductor device, a manufacturing method, and an electronic apparatus, and more particularly, relates to a semiconductor device, a manufacturing method, and an electronic apparatus in which quality can be further improved.

### BACKGROUND ART

In recent years, a technology for preparing a semiconductor device using a 3D integrated circuit by Wow (Wafer on Wafer) bonding which is to bond semiconductor wafers together or CoW (Chip on Wafer) bonding which is to bond a semiconductor chip to a semiconductor wafer has been developed. With this technology, a high-performance semiconductor device in which a plurality of chips having a variety of functions is bonded together, for example, can be manufactured.

Meanwhile, in a step of bonding semiconductor wafers together by WoW bonding or a step of bonding a semiconductor wafer and a semiconductor chip together by Cow bonding, stress which is generated by pressing during the bonding may cause strain in a device pattern of a semiconductor device.

For example, PTL 1 discloses a semiconductor device in which propagation of stress is interrupted by a groove formed in an outer peripheral portion of a chip region on a bonding surface of a support substrate, whereby strain due to bonding of wafers is relaxed.

### CITATION LIST

### Patent Literature

### PTL 1

Japanese Patent Laid-open No. 2012-204543

### SUMMARY

### Technical Problem

Meanwhile, PTL 1 discloses a technology of relaxing strain that is generated during Wow bonding, but does not disclose a technology for CoW bonding. For example, in a solid-state imaging element, when strain of a device pattern is generated by CoW bonding, light is inhibited from entering a photodiode from a lens. This leads to concern regarding degradation of the image quality.

The present disclosure has been made in view of the above circumstances, and is provided to improve the quality of a semiconductor device manufactured by CoW bonding.

### Solution to Problem

A semiconductor device according to one aspect of the present disclosure includes a first semiconductor chip, a second semiconductor chip that is bonded to the first semiconductor chip by Cow bonding, and a high-stress film that generates stress to cancel stress to be generated in the first semiconductor chip or the second semiconductor chip during Cow bonding.

A semiconductor device manufacturing method according to the one aspect of the present disclosure includes forming a high-stress film that generates stress to cancel stress to be generated in a first semiconductor chip or a second semiconductor chip during CoW bonding of bonding the second semiconductor chip to the first semiconductor chip.

An electronic apparatus according to the one aspect of the present invention includes a semiconductor device including a first semiconductor chip, a second semiconductor chip that is bonded to the first semiconductor chip by CoW bonding, and a high-stress film that generates stress to cancel stress to be generated in the first semiconductor chip or the second semiconductor chip during CoW bonding.

In the one aspect of the present disclosure, the high-stress film that generates stress to cancel stress to be generated in the first semiconductor chip or the second semiconductor chip during CoW bonding of bonding the second semiconductor chip to the first semiconductor chip is provided to the semiconductor device.

### BRIEF DESCRIPTION OF DRAWINGS

FIG. 1 is a block diagram depicting a configuration example of a first embodiment of an imaging element to which the present technology is applied.

FIG. 2 is a diagram depicting a simulation result of stress that is generated by CoW bonding and one example of a high-stress film.

FIG. 3 is a diagram depicting a cross-sectional view of a configuration example of a sensor chip.

FIG. 4 is a diagram for explaining a manufacturing method of the imaging element.

FIG. 5 is a diagram for explaining the manufacturing method of the imaging element.

FIG. 6 is a diagram for explaining the manufacturing method of the imaging element.

FIG. 7 is a diagram depicting modifications of the sensor chip.

FIG. 8 is a diagram for explaining a second embodiment of the imaging element.

FIG. 9 is a diagram for explaining a third embodiment of the imaging element.

FIG. 10 is a diagram for explaining a fourth embodiment of the imaging element.

FIG. 11 is a diagram for explaining a manufacturing method of the imaging element in FIG. 10.

FIG. 12 is a flowchart of a designing process of the imaging element.

FIG. 13 is a cross-sectional view of a second configuration example of the sensor chip.

FIG. 14 is a diagram depicting a modification of the Sensor chip in FIG. 13.

FIG. 15 is a cross-sectional view of a third configuration example of the sensor chip.

FIG. 16 is a diagram depicting a modification of the Sensor chip in FIG. 15.

FIG. 17 is a diagram for explaining a fifth embodiment of the imaging element.

FIG. 18 is a diagram for explaining a sixth embodiment of the imaging element.

FIG. 19 is a diagram for explaining a manufacturing method of the imaging element in FIG. 18.

FIG. 20 is a diagram for explaining the manufacturing method of the imaging element in FIG. 18.

FIG. 21 is a diagram for explaining a case in which the influence of a chip step is large.

FIG. 22 is a diagram for explaining a first modification of the imaging element in FIG. 18.

FIG. 23 is a diagram for explaining a second modification of the imaging element in FIG. 18.

FIG. 24 is a block diagram depicting a configuration example of an imaging apparatus.

FIG. 25 is a diagram depicting use cases of an image sensor.

### DESCRIPTION OF EMBODIMENTS

Hereinafter, specific embodiments to which the present technology is applied will be explained in detail with reference to the drawings.

### First Configuration Example of Imaging Element

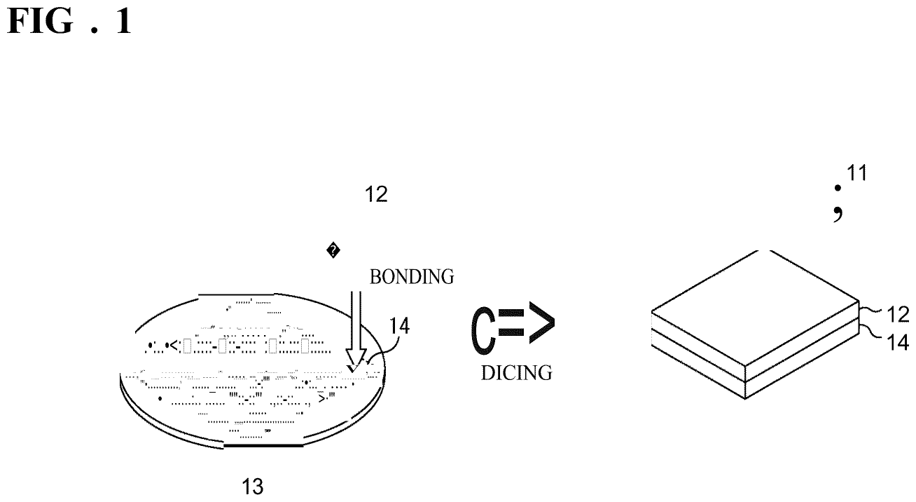

A first embodiment of an imaging element that is a semiconductor device to which the present technology is applied will be explained with reference to FIGS. 1 to 7.

As depicted in FIG. 1, first, a logic chip 12 on which a logic circuit for driving pixels etc. is formed is bonded by Cow bonding to a semiconductor wafer 13 that has not been cut into a plurality of sensor chips 14. Then, dicing along broken lines in the drawing is performed on the semiconductor wafer 13 such that the individual sensor chips 14 are formed. Accordingly, an imaging element 11 is manufactured. For example, the imaging element 11 is a lamination-type CMOS (Complementary Metal Oxide Semiconductor) image sensor in which the logic chip 12 and the sensor chip 14 of the same chip size are stacked.

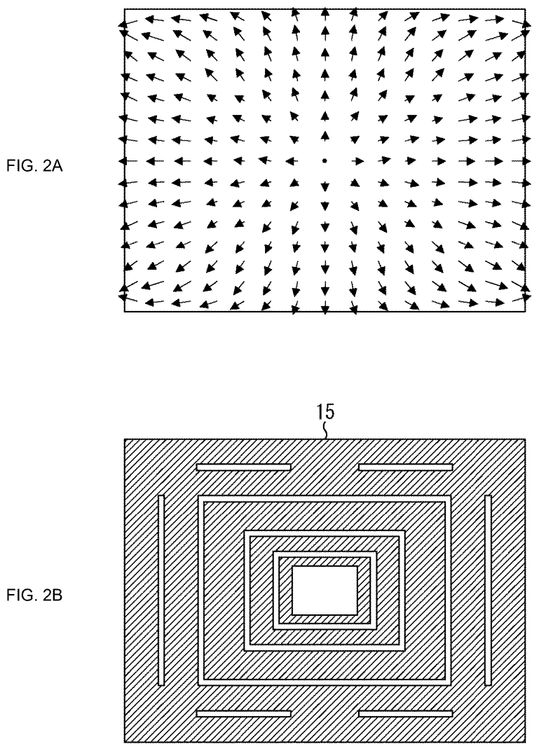

Further, the imaging element 11 has a configuration having a high-stress film 15 (see B of FIG. 2) disposed on the logic-chip-12 bonding surface side of the sensor chip 14 so as to suppress strain to be generated in a device pattern of the sensor chip 14 due to stress that is generated during Cow bonding of the logic chip 12 pressed against the semiconductor wafer 13.

In A of FIG. 2, depicted is one example of a simulation result obtained by simulating stress to be generated in the logic chip 12 during CoW bonding of the logic chip 12 pressed against the semiconductor wafer 13. In A of FIG. 2, each arrow indicates the direction and magnitude of stress to be generated at a point on the logic chip 12, and a rectangular frame line indicates an outer shape of the logic chip 12.

During CoW bonding of pressing the logic chip 12 against the semiconductor wafer 13, stress to expand the logic chip 12 is generated, as depicted in the drawing. Therefore, in an direction opposite to the stress, stress to contract the sensor chip 14 is generated in the sensor chip 14. In addition, stress generated by CoW bonding is larger in positions closer to the four corners of the logic chip 12 and the sensor chip 14, and is vertically and horizontally symmetrical with respect to the rectangular shape of the logic chip 12 and the sensor chip 14.

Consequently, the high-stress film 15 which is disposed on the sensor chip 14 generates stress to cancel stress contracting the sensor chip 14, and is formed in an arrangement pattern having higher density in a position closer to each of the four corners of the sensor chip 14 and being vertically and horizontally symmetrical with respect to the rectangular shape of the sensor chip 14.

For example, as a result of adjustment of the arrangement density with an arrangement pattern in which the high-stress film 15 has slits and openings (white blank portions) as depicted in B of FIG. 2, stress generated by CoW bonding to contract the sensor chip 14 can be adaptively cancelled. That is, the high-stress film 15 is formed in an arrangement pattern having density variations in which the density is high in regions close to the four corners where stress to contract the sensor chip 14 is large while the density is low in a region around the center where stress to contract the sensor chip 14 is small. Consequently, the high-stress film 15 is formed so as to generate large stress to expand the sensor chip 14 in the regions close to the four corners and generate small stress to contract sensor chip 14 in the region around the center.

In addition, in the imaging element 11 that has the logic chip 12 and the sensor chip 14 of the same chip size, the high-stress film 15 that has the same size as the logic chip 12 and the sensor chip 14 is disposed.

It is to be noted that the directions and magnitudes of stress to be generated vary according to the bonding method of the logic chip 12 and the sensor chip 14, but the density of such stress necessarily becomes high at the four corners of the logic chip 12 and the sensor chip 14, and is vertically and horizontally symmetrical with respect to the rectangular shape. Therefore, the arrangement pattern for providing density variations to the high-stress film 15 is required to have high density in the regions close to the four corners and to be vertically and horizontally symmetrical with respect to the rectangular shape.

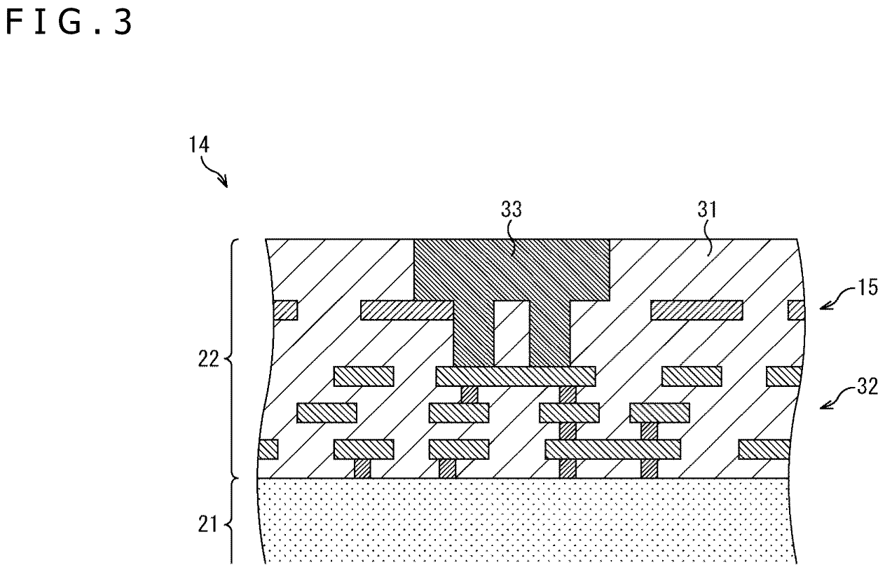

FIG. 3 is a diagram depicting a cross-sectional view of a configuration example of the sensor chip 14.

As depicted in FIG. 3, the sensor chip 14 is formed by stacking a wiring layer 22 on a semiconductor substrate 21 on which a photodiode etc. is disposed. In the wiring layer 22, multilayer (three layers in the drawing) wirings 32 are disposed in an interlayer insulation film 31, and the high-stress film 15 is disposed in a layer different from the wirings 32. Moreover, a bonding pad 33 which is used for bonding to the logic chip 12 is disposed so as to be exposed from a surface of the wiring layer 22, and the bonding pad 33 is connected to prescribed wirings 32.

In this manner, the sensor chip 14 can have the high-stress film 15 inside the wiring layer 22 which is on the logic-chip-12 bonding surface side. Therefore, with the high-stress film 15, generation of strain that is caused by stress to be generated in the sensor chip 14 during CoW bonding can be relaxed, and strain to be generated in the device pattern of the sensor chip 14 can be restrained.

Thus, strain that is generated in the device pattern of the sensor chip 14 can be restrained in the imaging element 11. As a result of this, lenses for respective pixels can be formed on a sensor surface of the sensor chip 14 so as to match arrangement of photodiodes that are formed in the sensor chip 14 for the respective pixels, for example. Accordingly, light is inhibited from entering the photodiodes from the lenses, so that the image quality of the imaging element 11 can be further improved.

Furthermore, the accuracy of bonding alignment between the logic chip 12 and the sensor chip 14 is enhanced in the imaging element 11. Accordingly, poor conductivity can be improved, for example.

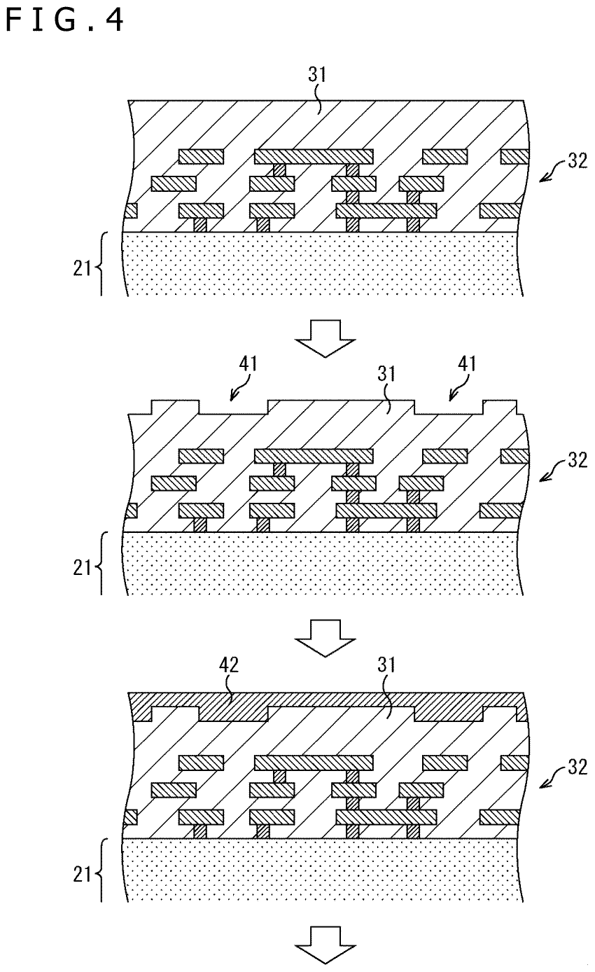

Steps of manufacturing the sensor chip 14 provided with the high-stress film 15 in the method for manufacturing the imaging element 11 will be explained with reference to FIGS. 4 to 6.

In a first step, the multilayer wirings 32 are formed inside the interlayer insulation film 31 while the interlayer insulation film 31 is stacked on a surface of the semiconductor substrate 21, as depicted in the upper section of FIG. 4.

In a second step, a recess 41 that conforms to the arrangement pattern of the high-stress film 15 is formed by dry-etching a surface of the interlayer insulation film 31, as depicted in the middle section of FIG. 4.

In a third step, a film of a material (e.g. silicon nitride) to become the high-stress film 15 is formed on a surface of the interlayer insulation film 31 and inside the recess 41, whereby a nitride film 42 is formed over the entire interlayer insulation film 31, as depicted in the lower section of FIG. 4.

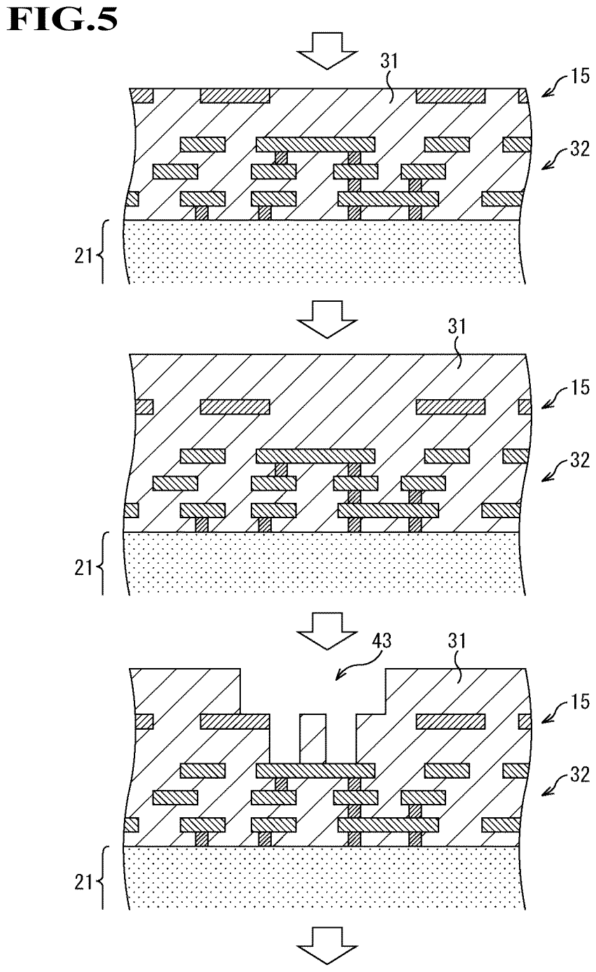

In a fourth step, the nitride film 42 formed on the surface of the interlayer insulation film 31 is removed by CMP (Chemical Mechanical Polishing), whereby the high-stress film 15 is formed, as depicted in the upper section of FIG. 5.

In a fifth step, the interlayer insulation film 31 is deposited until the thickness of the wiring layer 22 is reached, as depicted in the middle section of FIG. 5.

In a sixth step, a recess 43 that conforms to the shape of the bonding pad 33 is formed by dry-etching the surface of the interlayer insulation film 31, as depicted in the lower section of FIG. 5.

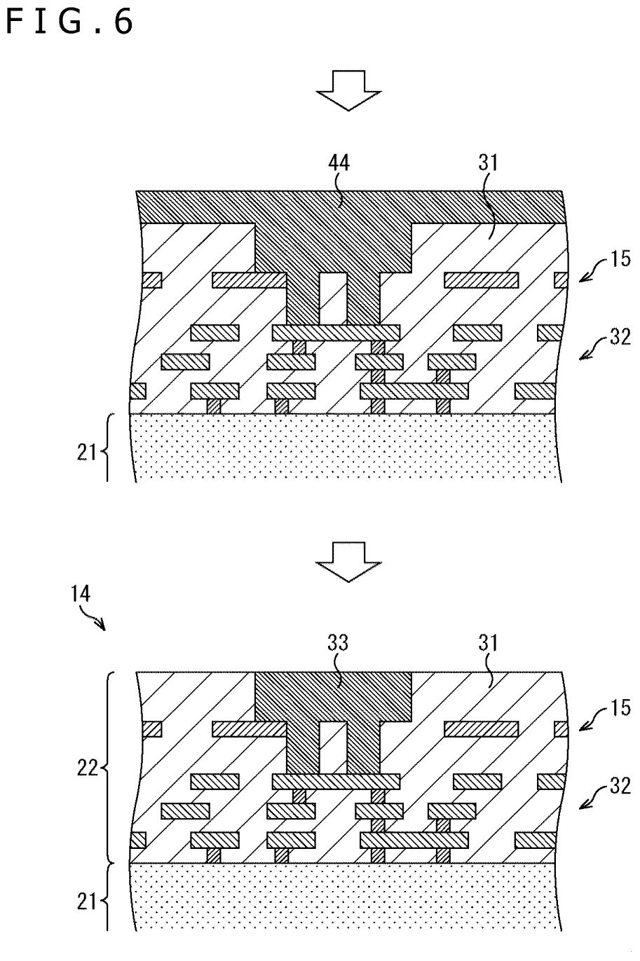

In a seventh step, a film of a metal material (e.g. copper) to become the bonding pad 33 is formed on the surface of the interlayer insulation film 31 and inside the recess 43, whereby a metal film 44 is formed over the entire interlayer insulation film 31, as depicted in the upper section of FIG. 6.

In an eighth step, the metal film 44 formed on the surface of the interlayer insulation film 31 is removed by CMP, whereby the bonding pad 33 is formed, as depicted in the lower section of FIG. 6.

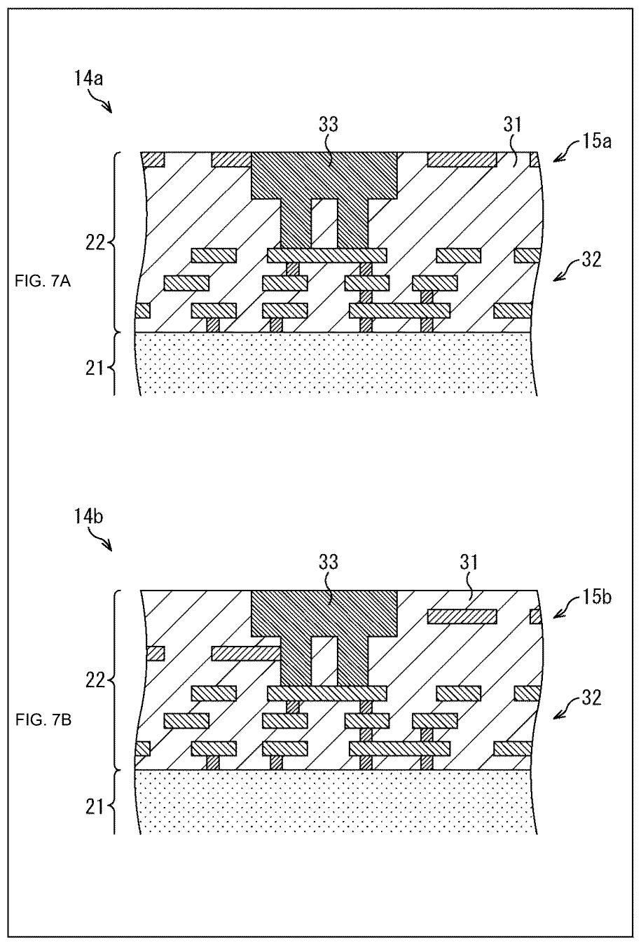

As a result of the above steps, the sensor chip 14 having the high-stress film 15 inside the wiring layer 22 can be FIG. 7 is a diagram depicting modifications of the sensor chip 14.

A of FIG. 7 depicts a cross-sectional view of a configuration example of a sensor chip 14a which is a first modification. For example, the sensor chip 14a is formed by disposing a high-stress film 15a on the outermost surface of the wiring layer 22.

B of FIG. 7 depicts a cross-sectional view of a configuration example of a sensor chip 14b which is a second modification. For example, the sensor chip 14b is formed by disposing a part and another part of the high-stress film 15b in different layers inside the wiring layer 22.

### Second Configuration Example of Imaging Element

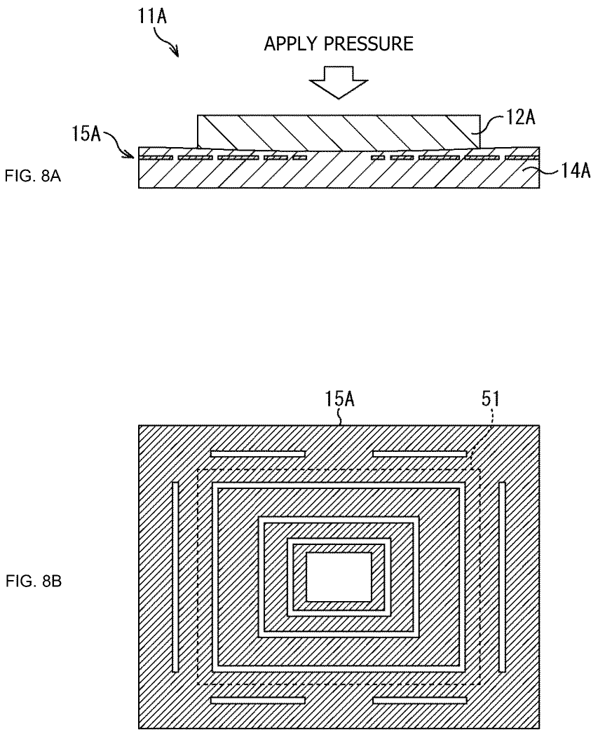

A second embodiment of the imaging element will be explained with reference to FIG. 8.

An imaging element 11A is formed by CoW bonding of a logic chip 12A to a sensor chip 14A having a larger chip size than the logic chip 12A, as depicted in a cross-sectional layout in A of FIG 8.

For example, when the Cow bonding is performed with the logic chip 12A being pressed against the sensor chip 14A, stress generated by the applied pressure leads to generation of strain in the sensor chip 14A over a range wider than the chip size of the logic chip 12A. In view of this, the imaging element 11A has a configuration in which the high-stress film 15A which is larger than the logic chip 12A is disposed on the logic-chip-12A bonding surface side of the sensor chip 14A such that strain generated in a range wider than the chip size of the logic chip 12A is restrained.

For example, a rectangular frame line 51 which is a broken line in B of FIG. 8 indicates the outer shape of the logic chip 12A, and the high-stress film 15A is disposed in a range, on the sensor chip 14A, wider than the logic chip 12A. In addition, the high-stress film 15A is formed in an arrangement pattern, which is similar to that of the high-stress film 15 in FIG. 2, having higher density in regions closer to the four corners of the sensor chip 14A and being vertically and horizontally symmetrical with respect to the rectangular shape of the sensor chip 14A.

In the imaging element 11A having the above configuration, strain to be generated in the device pattern of the sensor chip 14A can be restrained, as in the imaging element 11 in FIG. 1. Accordingly, image quality can be further improved, and poor conductivity can be further improved, for example.

### Third Configuration Example of Imaging Element

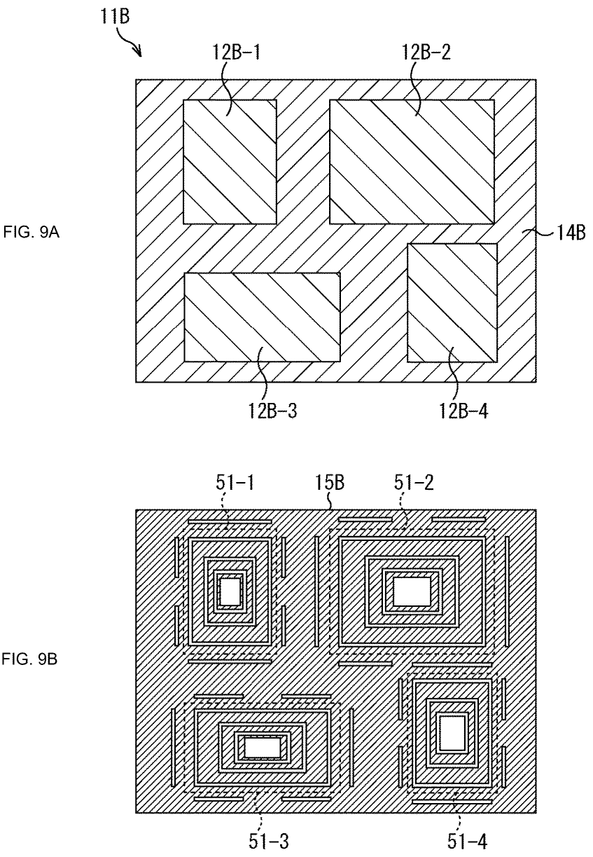

A third embodiment of the imaging element will be explained with reference to FIG. 9.

An imaging element 11B is formed by CoW bonding of four logic chips 12B-1 to 12B-4 to a sensor chip 14B that has a larger chip size than the logic chips 12B-1 to 12B-4, as depicted in a plane layout in A of FIG. 9. That is, a lamination structure in which a plurality of the logic chips 12B is stacked on the sensor chip 14B can be adopted for the imaging element 11B.

For example, when the CoW bonding is performed with the logic chips 12B-1 to 12B-4 being pressed against the sensor chip 14B, stress generated by the applied pressure leads to generation of strain in the sensor chip 14B over a range wider than the chip size of the logic chips 12B-1 to 12B-4. In view of this, the imaging element 11B has a configuration in which a high-stress film 15B is disposed over the entire sensor chip 14B so as to restrain strain generated in an area wider than the chip size of the logic chips 12B-1 to 12B-4.

For example, rectangular frame lines 51-1 to 51-4 which are broken lines in B of FIG. 9 respectively indicate the outer shapes of the logic chips 12B-1 to 12B-4. The high-stress film 15B is disposed, on the sensor chip 14B, in an area wider than the logic chips 12B-1 to 12B-4. Furthermore, like the high-stress film 15 in FIG. 2, the high-stress film 15B is formed in an arrangement pattern having higher density in regions closer to the four corners of the logic chips 12B-1 to 12B-4 and being vertically and horizontally symmetrical with respect to each of the rectangular shapes of the logic chips 12B-1 to 12B-4.

Also in the imaging element 11B having the above configuration, strain to be generated in the device pattern of the sensor chip 14B can be restrained, as in the imaging element 11 in FIG. 1. Accordingly, image quality can be further improved, and poor conductivity can be further improved, for example.

### Fourth Configuration Example of Imaging Element

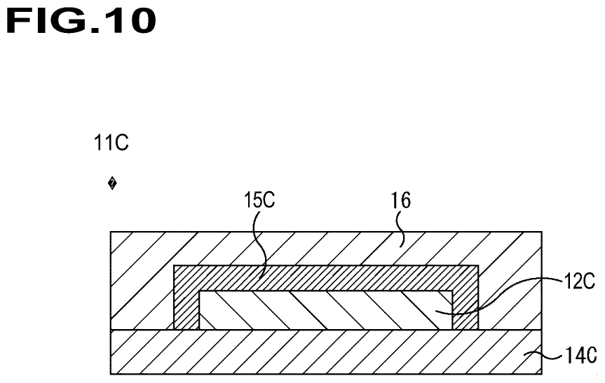

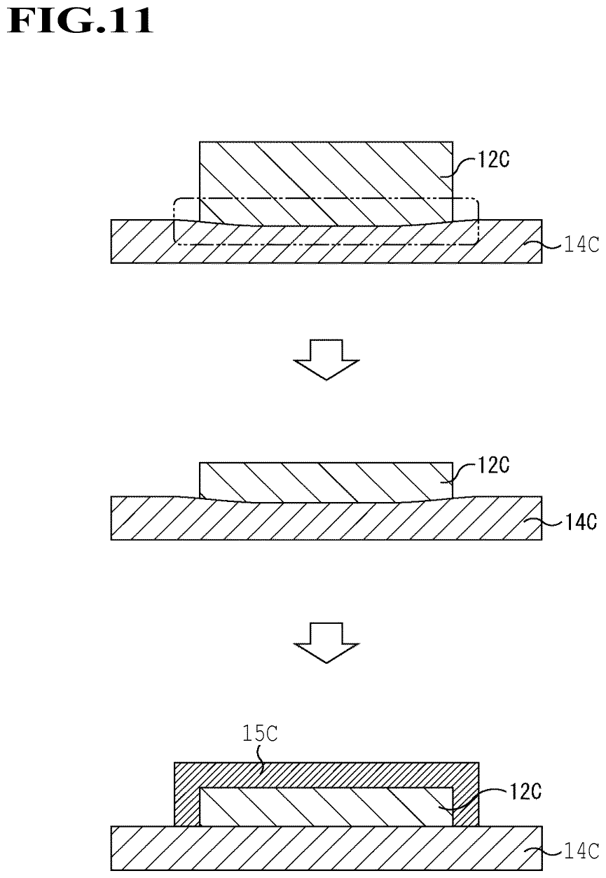

A fourth embodiment of the imaging element will be explained with reference to FIGS. 10 and 11.

An imaging element 11C is formed by CoW bonding of a logic chip 12C to a sensor chip 14C that has a larger chip size than the logic chip 12C, as depicted in a sectional layout in FIG. 10. In addition, in the imaging element 11C, a high-stress film 15C is disposed so as to cover the logic chip 12C in an area wider than the logic chip 12C, and an insulation film 16 is disposed so as to be stacked on the sensor chip 14C and the high-stress film 15C.

For example, the imaging element 11A in FIG. 8 has a structure in which the high-stress film 15A disposed on the logic-chip-12A bonding surface side of the sensor chip 14A relaxes generation of strain inside the sensor chip 14A. In contrast, the imaging element 11C has a structure in which the high-stress film 15C that is disposed so as to cover the logic chip 12C after Cow bonding of the logic chip 12C to the sensor chip 14C relaxes generation of strain from the outside of the sensor chip 14C.

It is to be noted that, like the high-stress film 15A depicted in B Of FIG. 8, the high-stress film 15C is formed in the arrangement pattern having higher density in regions closer to the four corners of the sensor chip 14C and being vertically and horizontally symmetrical with respect to the rectangular shape of the sensor chip 14, although this arrangement pattern is not depicted.

Also, in a case where Cow bonding of a plurality of the logic chips 12C to the sensor chip 14C is performed as in the imaging element 11B in FIG. 9, the high-stress film 15C is disposed so as to cover the logic chips 12C.

Also in the imaging element 11C having the above configuration, strain to be generated in the device pattern of the sensor chip 14C can be restrained, as in the imaging element 11 in FIG. 1. Accordingly, image quality can be further improved, for example.

FIG. 11 depicts one example of a manufacturing method of the imaging element 11C.

In an eleventh step, CoW bonding of the logic chip 12C to the sensor chip 14C is performed, as depicted in the upper section of FIG. 11. During this CoW bonding, strain of the sensor chip 14C is generated in an area surrounded by a dashed-and-double-dotted line, that is, in an area wider than the logic

In a twelfth step, the thickness of the logic chip 12C is reduced by, for example, polishing the logic chip 12C, as depicted in the middle section of FIG. 11.

In a thirteenth step, the high-stress film 15C is formed so as to cover the logic chip 12C, as depicted in the lower section of FIG. 11.

Subsequently, the insulation film 16 is formed. Accordingly, the imaging element 11C depicted in FIG. 10 can be manufactured.

### Designing Process of Imaging Element

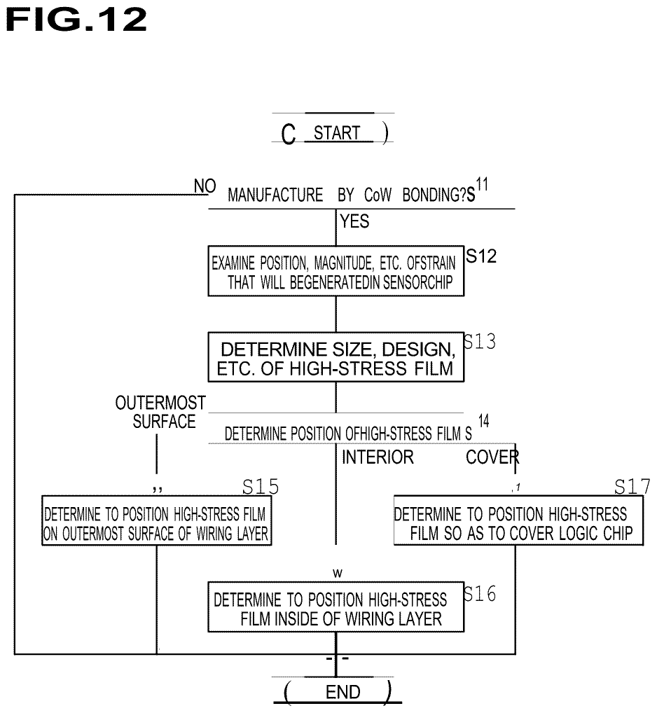

A designing process of the imaging element 11 will be explained with reference to a flowchart in FIG. 12.

For example, when the designing process of the imaging element 11 is started, whether or not to manufacture the imaging element 11 by CoW bonding is determined in step S11.

In a case where it is determined, in step S11, to refrain from manufacturing the imaging element 11 by Cow bonding, the process exits. In a case where it is determined to manufacture the imaging element 11 by Cow bonding, the process proceeds to step S12.

In step S12, a simulation for obtaining stress to be generated in the sensor chip 14 is carried out, and the position, magnitude, etc. of strain that will be generated in the sensor chip 14 are examined on the basis of the simulation result. In this step, a configuration to be manufactured, such as the configuration in which the logic chip 12 and the sensor chip 14 have the same chip size (see FIG. 1), the configuration in which the logic chip 12 and the sensor chip 14 have different chip sizes (see FIG. 8), or the configuration in which a plurality of the logic chips 12 are bonded to the sensor chip 14 (see FIG. 9), is simulated.

In step S13, the size and design of the high-stress film 15 are determined according to the position, magnitude, etc. of strain examined in step S12. For example, the size and design of the high-stress film 15 are determined such that the density becomes high in a position where large strain is generated while the density becomes low in a position where small strain is generated.

In step S14, which of the outermost surface of the wiring layer 22, the inside of the wiring layer 22, and a position to cover the logic chip 12 is the position of the high-stress film 15 is determined according to the configuration of the imaging element 11 to be manufactured.

In a case where it is determined, in step S14, to position the high-stress film 15 on the outermost surface of the wiring layer 22, the process proceeds to step S15 in which the high-stress film 15 is determined to be positioned on the outermost surface of the wiring layer 22. That is, in this case, the imaging element 11 is manufactured with the configuration of the sensor chip 14a depicted in A of FIG. 7.

On the other hand, in a case where it is determined, in step S14, to position the high-stress film 15 inside the wiring layer 22, the process proceeds to step S16 in which the high-stress film 15 is determined to be positioned inside the wiring layer 22. That is, in this case, the imaging element 11 is manufactured with the configuration of the sensor chip 14 depicted in FIG. 3.

On the other hand, in a case where it is determined, in step S15, to position the high-stress film 15 so as to cover the logic chip 12, the process proceeds to step S17 in which the high-stress film 15 is determined to be positioned so as to cover the logic chip 12. That is, in this case, the imaging element 11C depicted in FIG. 10 is manufactured.

Then, after steps S15 to S17, the designing process of the imaging element 11 exits, and then, the imaging element 11 is manufactured according to the determination made in the designing process.

As explained so far, according to the designing process according to the configuration of the imaging element 11 to be manufactured, the imaging element 11 in which strain that will be generated in the device pattern can be appropriately restrained can be manufactured.

### Second Configuration Example of Sensor Chip

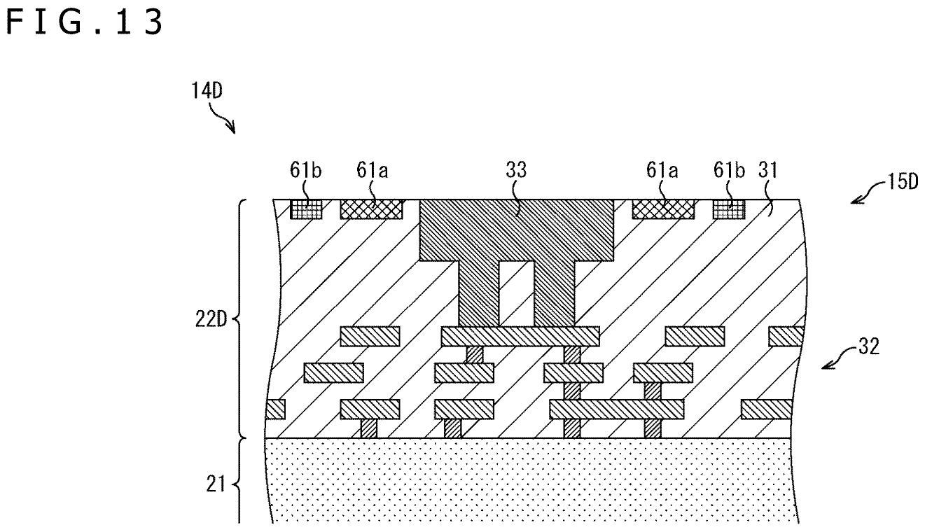

A sensor chip 14D which is a second configuration example will be explained with reference to FIG. 13. It is to be noted that a component in the sensor chip 14D depicted in FIG. 13 that is similar to that in the sensor chip 14 depicted in FIG. 3 will be denoted by the same reference sign, and a detailed explanation thereof will be omitted.

As depicted in FIG. 13, the sensor chip 14D has the configuration common to the sensor chip 14 in FIG. 3, in which the sensor chip 14D is formed by stacking a wiring layer 22D on the semiconductor substrate 21, the wirings 32 are disposed inside the wiring layer 22D, and the bonding pad 33 is disposed so as to be exposed from a surface of the wiring layer 22D.

In addition, like the sensor chip 14 in FIG. 3, the sensor chip 14D has a high-stress film 15D disposed in a layer different from those of the wirings 32 in the wiring layer 22D, but the sensor chip 14D is different from the sensor chip 14 in FIG. 3 because the high-stress film 15D includes at least two or more kinds of materials.

In the example depicted in FIG. 13, the high-stress film 15D includes a high-stress film 61a that includes a first material and a high-stress film 61b that includes a second material. For example, silicon nitride (Si₃N₄), silicon carbide (SiC), silicon carbonitride (SiCN), silicon oxide that contains carbon, hydrogen, or nitrogen, or the like may be used as the materials of the high-stress film 61a and the high-stress film 61b. In another case, aluminum oxide (Al₂O₃), aluminum nitride (AlN), tantalum, tantalum nitride (TaN), titanium, titanium nitride (TiN), tungsten, tungsten nitride (WN), or the like may be used as the materials of the high-stress film 61a and the high-stress film 61b.

Further, in the high-stress film 15D, the high-stress film 61a and the high-stress film 61b are disposed in a region, for example, where pressure is applied during Cow bonding, so as to cancel contraction stress that will be generated after CoW bonding, in consideration of strain to be generated by Cow bonding. For example, in the high-stress film 15D, the high-stress film 61a using a material that has a relatively strong force for canceling stress is disposed in a region where stress to be generated by CoW bonding so as to contract the sensor chip 14D is large while the high-stress film 61b using a material that has a relatively weak force for canceling stress is disposed in a region where stress to be generated by Cow bonding so as to contract the sensor chip 14D is small.

Accordingly, generation of strain that is caused by stress to be generated during CoW bonding is effectively relaxed with the high-stress film 15D in the sensor chip 14D. Thus, the quality can be further improved.

In addition, the high-stress film 15D which includes multiple kinds of materials can be formed by, for example, repeating, for each of the materials, the second to fifth steps in the manufacturing method which has been previously explained with reference to FIGS. 4 to 6.

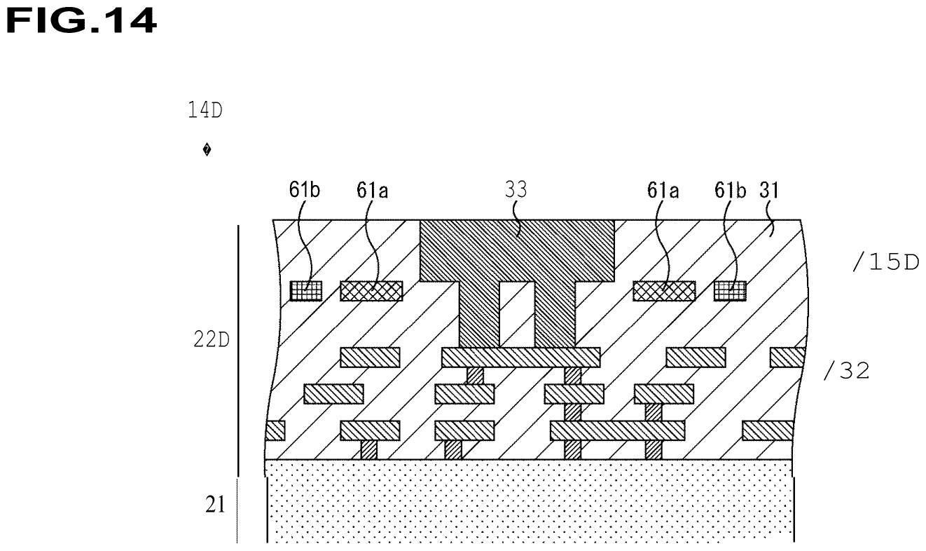

It is to be noted that, in the example depicted in FIG. 13, the sensor chip 14D is formed with the high-stress film 15D disposed on the outermost surface of the wiring layer 22D, but may be formed with the high-stress film 15D disposed in a position other than the outermost surface of the wiring layer 22D. That is, even if the sensor chip 14D has the high-stress film 15D inside the wiring layer 22D as in the modification depicted in FIG. 14, the quality can be improved.

### Third Configuration Example of Sensor Chip

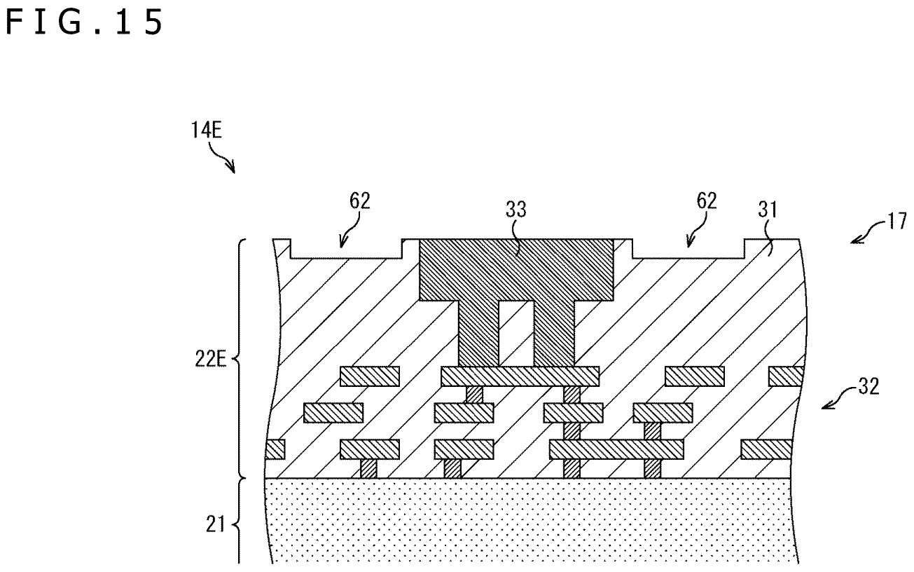

A sensor chip 14E which is a third configuration example will be explained with reference to FIG. 15. It is to be noted that a component of the sensor chip 14E depicted in FIG. 15 similar to that of the sensor chip 14 depicted in FIG. 3 is denoted by the same reference sign, and a detailed explanation thereof will be omitted.

As depicted in FIG. 15, the sensor chip 14E has the configuration common to the sensor chip 14 in FIG. 3 in which a wiring layer 22E is stacked on the semiconductor substrate 21, the wirings 32 are disposed inside the wiring layer 22E, and the bonding pad 33 is disposed so as to be exposed from a surface of the wiring layer 22E.

On the other hand, the sensor chip 14E has a different configuration from that of the sensor chip 14 in FIG. 3 because, in place of the high-stress film 15, an air gap layer 17 is disposed in a layer different from those of the wirings 32 in the wiring layer 22E.

In the example depicted in FIG. 15, an air gap 62 constituting the air gap layer 17 is formed as a recess because the air gap layer 17 is disposed on the outermost surface of the wiring layer 22E. Further, the air gap layer 17 has a configuration in which the air gap 62 is disposed, for example, in an area to which pressure will be applied during CoW bonding, so as to release generated contraction stress after the Cow bonding (to prevent such stress from being applied to the sensor chip 14E).

Accordingly, generation of strain that is caused by stress to be generated during CoW bonding is effectively relaxed with the air gap layer 17 in the sensor chip 14E. Thus, the quality can be further improved.

In addition, the air gap layer 17 can be formed by, for example, forming the recess 41 in the second step and then refraining from embedding a material to become the high-stress film 15 in the manufacturing method which has been explained with reference to FIGS. 4 to 6.

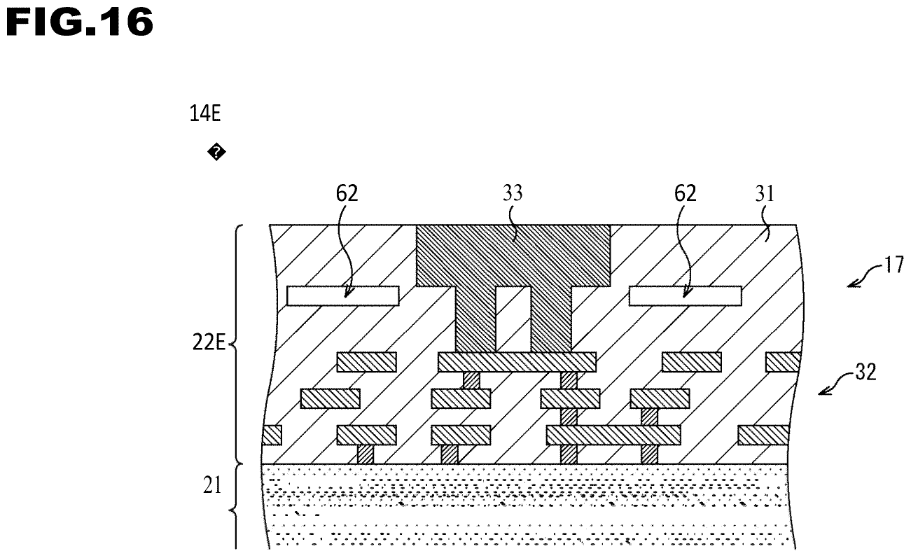

It is to be noted that the sensor chip 14E in the example depicted in FIG. 15 is formed with the air gap layer 17 disposed on the outermost surface of the wiring layer 22E but the air gap layer 17 may be disposed in a position other than the outermost surface of the wiring layer 22E. That is, even if the sensor chip 14E has the air gap layer 17 inside the wiring layer 22E, as in a modification depicted in FIG. 16, the quality still can be improved.

### Fifth Configuration Example pf Imaging Element

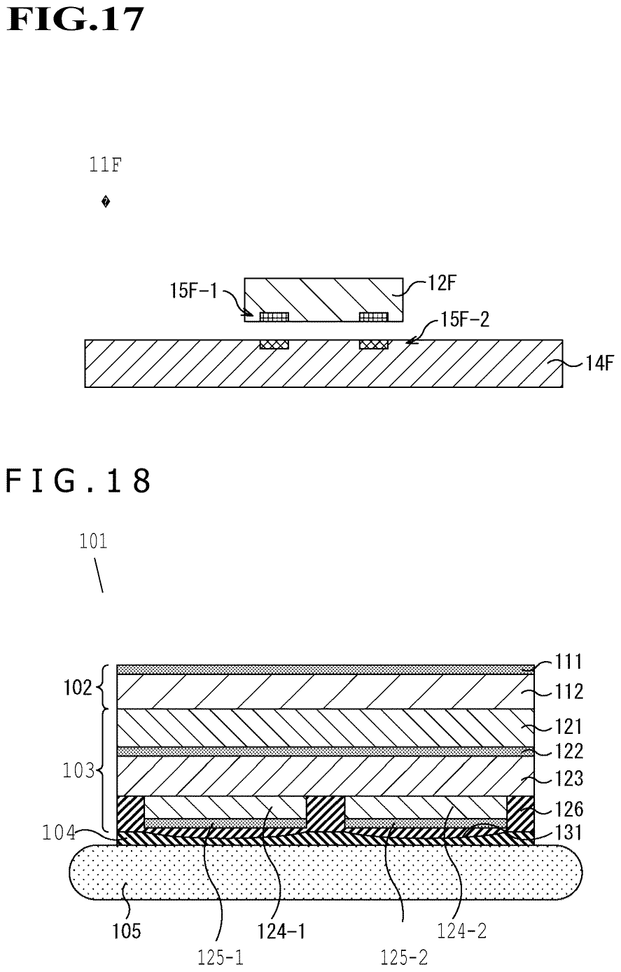

A fifth embodiment of the imaging element will be explained with reference to FIG. 17.

An imaging element 11F is formed by CoW bonding of a logic chip 12F to a sensor chip 14F having a larger chip size than the logic chip 12F, as depicted as a cross-sectional layout in FIG. 17. Further, in the imaging element 11F, a high-stress film 15F-1 is disposed in the logic chip 12F while a high-stress film 15F-2 is disposed in the sensor chip 14F. That is, the imaging element 11F is formed by providing the high-stress films 15F to both the logic chip 12F and the sensor chip 14F.

For example, the high-stress film 15F-1 is disposed so as to restrain outward extension toward the logic chip 12F from being generated by pressure during Cow bonding. Likewise, the high-stress film 15F-2 is disposed so as to restrain outward extension toward the sensor chip 14F from being generated by pressure during CoW bonding. Since generation of outward extension during CoW bonding is restrained by the high-stress film 15F-1 and the high-stress film 15F-2 in this manner, generation of contraction stress in the logic chip 12F and the sensor chip 14F after the CoW bonding can be restrained.

Therefore, generation of contraction stress in the logic chip 12F and the sensor chip 14F due to CoW bonding is restrained in the imaging element 11F, so that generation of strain in the sensor surface, for example, is restrained. Accordingly, the image quality can be further improved.

It is to be noted that the imaging element 11F may be configured to relax generation of strain that is caused by stress to be generated during CoW bonding with the air gap layer 17, which has been explained with reference to FIG. 15, in place of the high-stress film 15F-1 and the high-stress film 15F-2.

### Sixth Configuration Example of Imaging Element

A sixth embodiment of the imaging element will be explained with reference to FIGS. 18 to 23.

FIG. 18 is a cross section of a configuration example of the imaging element 101 that is a semiconductor device to which the present technology is applied.

As depicted in FIG. 18, the imaging element 101 is formed by stacking a sensor chip 102, a logic chip 103, a strain adjustment film 104, and a support substrate 105.

The sensor chip 102 is formed by stacking a wiring layer 112 on a semiconductor substrate 111 on which a photodiode or the like is disposed.

The logic chip 103 is formed by stacking a wiring layer 121, a semiconductor substrate 122, a wiring layer 123, wiring layers 124-1 and 124-2, semiconductor substrates 125-1 and 125-2, and an embedding layer 126. That is, the logic chip 103 is formed by bonding a small chip including the wiring layers 124-1 and the semiconductor substrate 125-1 and a small chip including the wiring layer 124-2 and the semiconductor substrate 125-2 to a large chip including the wiring layer 121, the semiconductor substrate 122, and the wiring layer 123. Therefore, the logic chip 103 has a shape in which a step projected toward the wiring layer 123 is provided between the wiring layer 124-1 and the semiconductor substrate 125-1 on one hand and the wiring layer 124-2 and the semiconductor substrate 125-2 on the other hand. Further, the embedding layer 126 to embed the step is formed on the logic chip 103, whereby a surface (downwardly facing surface in FIG. 18) bonded to the support substrate 105 via the strain adjustment film 104 is flattened.

Here, the embedding layer 126 is formed by performing film formation on a surface of the small chip including the wiring layer 124-1 and the semiconductor substrate 125-1, on a surface of the small chip formed including the wiring layer 124-2 and the semiconductor substrate 125-2, and between these small chips by CVD (Chemical Vapor Deposition) or the like, and then, flattening the surfaces by CMP (Chemical Mechanical Polishing). However, due to the abovementioned step projected toward the wiring layer 123, unevenness (hereinafter, referred to as chip steps) is generated on a surface of the embedding layer 126 even if flattening is performed by CMP.

Then, in a case where the support substrate 105 is bonded while the surface of the embedding layer 126 has a chip step, for example, the influence of the chip step may be exerted on the surface after thickness reduction of the semiconductor substrate 111. If so, strain is generated in longitudinal and lateral directions of a sensor surface of the sensor chip 102. Such strain causes misalignment or defocus in a lithography process subsequent to WoW bonding. This results in the influence of mixed colors and deterioration of yield due to generation of abnormality in pattern formation, with regards to device characteristics.

The strain adjustment film 104 is disposed in order to restrain the influence of the chip step on the surface of such an embedding layer 126 and adjust strain generated in the sensor surface of the sensor chip 102. For example, before the logic chip 103 is bonded to the support substrate 105, an SFQR (Site Front least sQuare Range) value of the surface of the embedding layer 126 is measured, and an uneven surface 131 to negate the unevenness of the surface of the embedding layer 126 is formed on the strain adjustment film 104 according to the SFOR value. That is, the logic-chip-103 bonding surface of the strain adjustment film 104 is the uneven surface 131 that is projected according to a recess in the surface of the embedding layer 126 and is recessed according to a projection on the surface of the embedding layer 126. Since the uneven surface 131 is disposed on the strain adjustment film 104 in this manner, the influence of a chip step on the surface of the embedding layer 126 can be negated.

The support substrate 105 is a base for supporting the Sensor chip 102 and the logic chip 103.

Since the imaging element 101 has the above configuration, the influence of a chip step on the surface of the embedding layer 126 is negated by the strain adjustment film 104, so that generation of strain in a surface of the semiconductor substrate 111 having undergone thickness reduction can be restrained. As a result, degradation of device characteristics and deterioration of yield in the imaging element 101 can be avoided. Accordingly, the quality can be further improved.

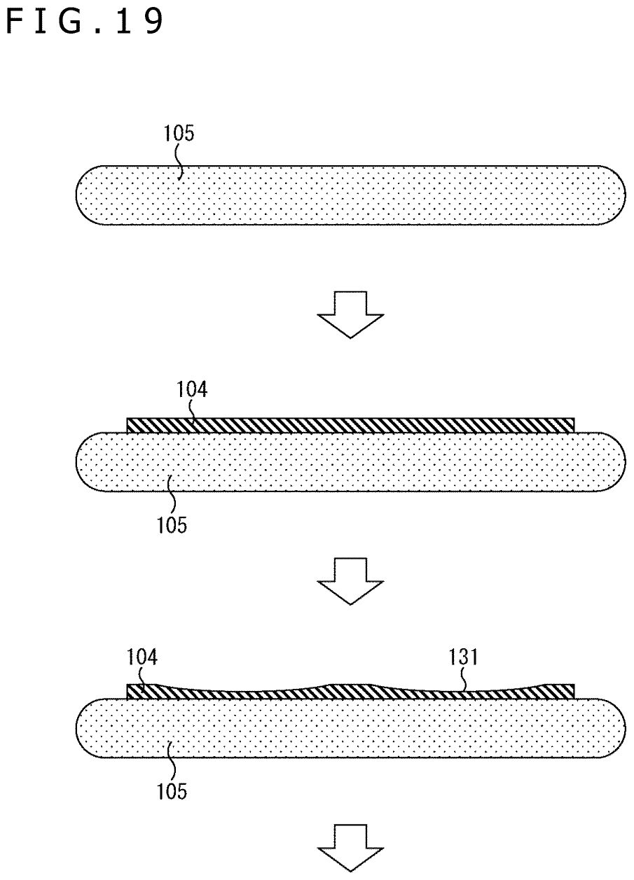

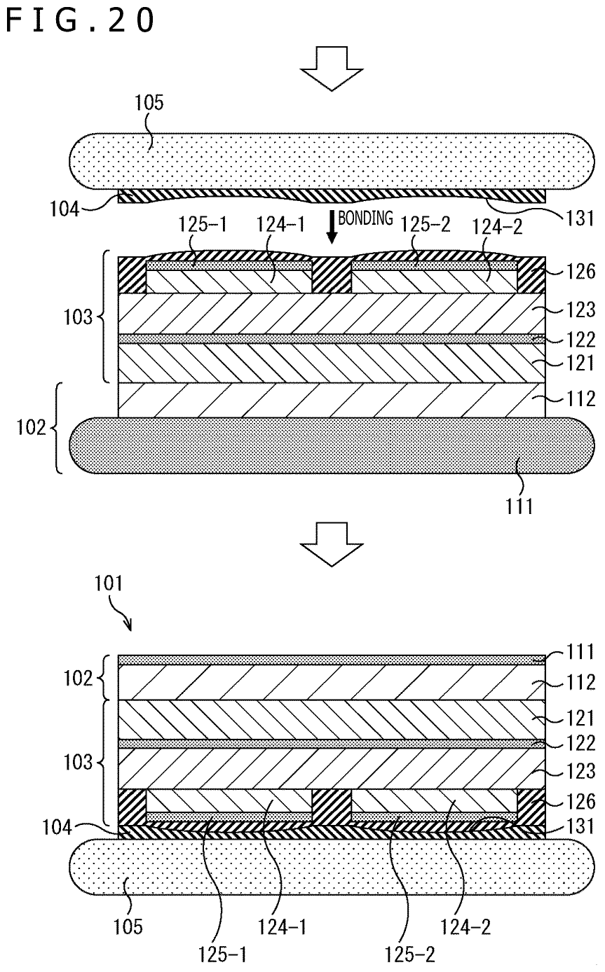

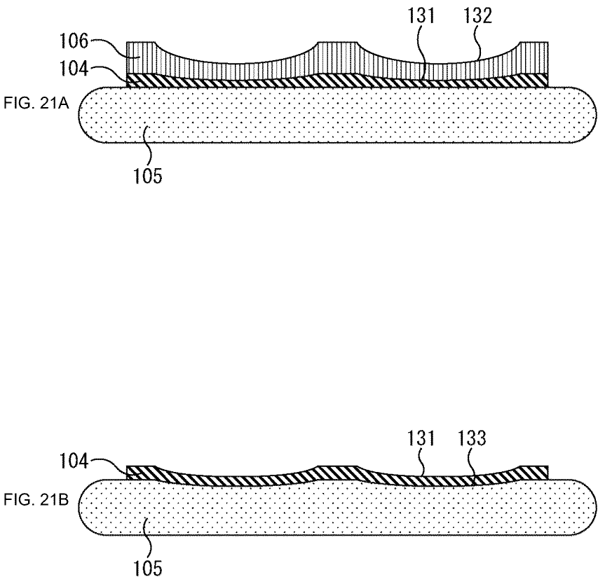

A manufacturing method of the imaging element 101 will be explained with reference to FIGS. 19 and 20.

In a twenty-first step, the support substrate 105 is prepared, as depicted in the upper section of FIG. 19.

In a twenty-second step, the strain adjustment film 104 is formed on the support substrate 105, as depicted in the middle section of FIG. 19. Examples of a film forming species of the strain adjustment film 104 include silicon nitride (SiN), silicon oxide (SiO), silicon carbonitride (SiCN), silicon carbide (SiC), titanium nitride (TiN), and amorphous carbon. It is to be noted that a silicon-based film can be adjusted for both a tension side and a contraction side according to a film formation condition.

In a twenty-third step, the uneven surface 131 is formed by locally etching a surface of the strain adjustment film 104, as depicted in the lower section of FIG. 19. For example, the uneven surface 131 is formed so as to cancel the influence of a chip step according to an SFOR value of the surface of the embedding layer 126.

In a twenty-fourth step, the strain adjustment film 104 stacked on the support substrate 105 is set as a bonding surface, and bonding to the embedding layer 126 on the logic chip 103 is performed, as depicted in the upper section of FIG. 20. Here, the semiconductor substrate 111 of the sensor chip 102 is in a state prior to thickness reduction.

In a twenty-fifth step, the thickness of the semiconductor substrate 111 is reduced, as depicted in the lower section of FIG. 20. Accordingly, the imaging element 101 is manufactured.

Since the uneven surface 131 is formed in this manner on a surface of the strain adjustment film 104 according to an SFOR value that is measured prior to bonding of the logic chip 103 to the support substrate 105, generation of strain in a surface of the semiconductor substrate 111 having undergone thickness reduction can be restrained. Consequently, the imaging element 101 can be manufactured with higher quality.

A case where the influence of a chip step on the surface of the embedding layer 126 is large will be explained with reference to FIG. 21.

For example, in a case where the SFOR value of the surface of the embedding layer 126 is large, there is a concern regarding degradation of the strain correction effect if the strain adjustment film 104 is excessively etched to form a deeper recess.

Therefore, as depicted in A of FIG. 21, a second strain adjustment film 106 having small stress is additionally formed on the strain adjustment film 104 on which the uneven surface 131 has been formed, and the second strain adjustment film 106 is etched, whereby an uneven surface 132 that is recessed more deeply than the uneven surface 131 can be formed. Accordingly, even in a case where the influence of a chip step on the surface of the embedding layer 126 is large, the influence of the chip step can be more reliably negated.

Alternatively, as depicted in B of FIG. 21, the uneven surface 133 is formed by etching the support substrate 105 in consideration of the chip size, and the strain adjustment film 104 is formed on the uneven surface 133, whereby the uneven surface 131 that is more deeply recessed can be formed. Accordingly, even in a case where the influence of a chip step on the surface of the embedding layer 126 is large, an effect of more reliably negating the influence of the chip step can be obtained.

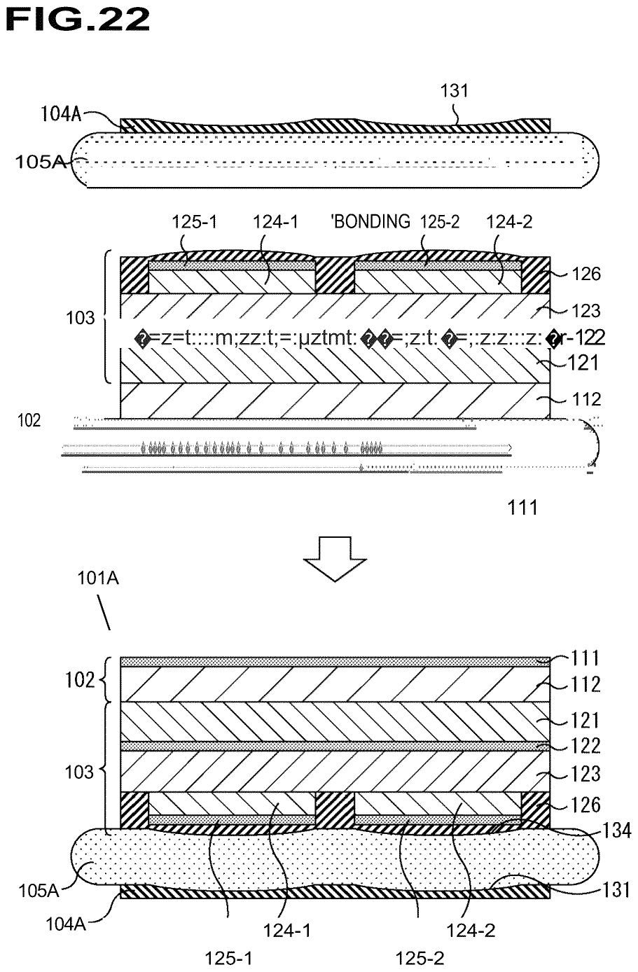

A first modification of the imaging element 101 will be explained with reference to FIG. 22. It is to be noted that a component of an imaging element 101A depicted in FIG. 22 similar to that of the imaging element 101 in FIG. 18 will be denoted by the same reference sign, and a detailed explanation thereof will be omitted.

As depicted in the lower side of FIG. 22, the imaging element 101A has the configuration common to that of the imaging element 101 in FIG. 18, in which the sensor chip 102 and the logic chip 103 are stacked.

On the other hand, the imaging element 101A has a configuration in which a support substrate 105A is stacked on the logic chip 103 and a strain adjustment film 104A is stacked on a surface opposite to the logic-chip-103 bonding surface of the support substrate 105A. This configuration is different from that of the imaging element 101 in FIG. 18.

That is, the surface of the support substrate 105A on which the strain adjustment film 104A is not stacked is pressed against the embedding layer 126 when the support substrate 105A is bonded to the logic chip 103, as depicted in the upper side of FIG. 22, so that the support substrate 105A is bonded to the logic chip 103. Here, a pressing force is applied to the uneven surface 131 of the strain adjustment film 104A. Therefore, a surface of the strain adjustment film 104A is flattened, and the uneven surface 131 is disposed on the other surface of the strain adjustment film 104A. Accordingly, an uneven surface 134 conforming to the shape of the uneven surface 131 is formed on the logic-chip-103 bonding surface of the support substrate 105A.

The uneven surface 131 is formed so as to negate the unevenness of the surface of the embedding layer 126, as previously explained, and the uneven surface 134 formed on the support substrate 105 also has a shape to negate the unevenness of the surface of the embedding layer 126.

Consequently, generation of strain of a surface of the semiconductor substrate 111 having undergone thickness reduction can be restrained in the imaging element 101A, as in the imaging element 101 in FIG. 18. Accordingly, the quality can be further improved.

That is, in both the configuration in which the strain adjustment film 104 is formed on the logic-chip-103 bonding surface of the support substrate 105A as in the imaging element 101 in FIG. 18 and the configuration in which the strain adjustment film 104A is formed on a surface opposite to the logic-chip-103 bonding surface of the support substrate 105A as in the imaging element 101A in FIG. 22, the influence of a chip step on the surface of the embedding layer 126 can be negated.

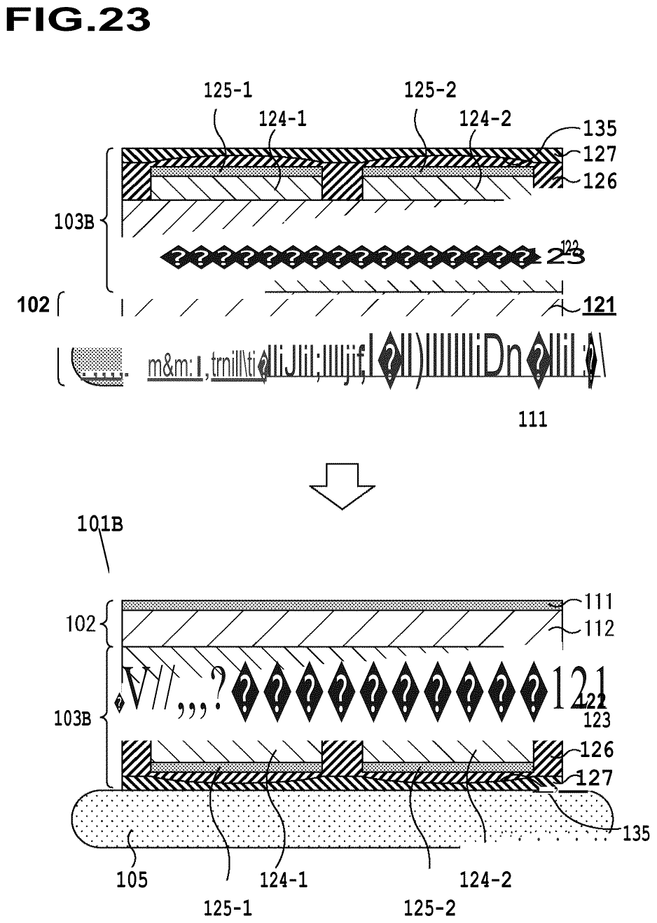

A second modification of the imaging element 101 will be explained with reference to FIG. 23. It is to be noted that a component of an imaging element 101B depicted in FIG. 23 common to that of the imaging element 101 in FIG. 18 will be denoted by the same reference sign, and a detailed explanation thereof will be omitted.

As depicted in the lower side of FIG. 23, the imaging element 101B has the configuration common to that of the imaging element 101 in FIG. 18 in which the sensor chip 102 and a logic chip 103B are stacked.

On the other hand, the imaging element 101B has a configuration in which a strain adjustment film 127 is disposed on the logic chip 103B and the support substrate 105 is bonded to the strain adjustment film 127. This configuration is different from that of the imaging element 101 in FIG. 18.

That is, as depicted in the upper side of FIG. 23, the logic chip 103B has a configuration in which a two-layer structure of the embedding layer 126 and the strain adjustment film 127 is provided in a stage prior to bonding of the support substrate 105. The embedding layer 126 is disposed in order to embed a step projected toward the wiring layer 123. The strain adjustment film 127 is formed for the embedding layer 126. Like the strain adjustment film 104 in FIG. 18, the strain adjustment film 127 is also disposed in order to improve the flatness of the support-substrate-105 bonding surface by canceling a chip step on the surface of the embedding layer 126 and to relax strain (stress) after Wow bonding. For example, the strain adjustment film 127 may be locally etched so as to be flat after thickness reduction of the semiconductor substrate 111.

Then, the embedding layer 126 and the strain adjustment film 127 include respective film types and film qualities of characteristics that are suited for the corresponding purposes. Examples of a film forming species of the strain adjustment film 104 include silicon nitride (SiN), silicon oxide (SiO), silicon carbonitride (SiCN), silicon carbide (SiC), titanium nitride (TiN), and amorphous carbon. It is to be noted that a silicon-based film can be adjusted for both a tension side and a contraction side according to a film formation condition.

Generation of strain in a surface of the semiconductor substrate 111 having undergone thickness reduction can be restrained also in the imaging element 101B thus configured, as in the imaging element 101 in FIG. 18. Accordingly, the quality can be further improved.

It is to be noted that the configuration example in which the high-stress film 15 is disposed in the sensor chip 14 has been explained in the present embodiment, but the high-stress film 15 may be disposed in the logic chip 12 in order to relax strain of a device pattern of the logic chip 12, for example. Needless to say, the high-stress films 15 can be disposed in both the logic chip 12 and the sensor chip 14.

In addition, the present technology is not limited to the imaging element 11, and is applicable to a variety of semiconductor devices manufactured by CoW bonding. With the present technology, the qualities of these semiconductor devices can be improved.

It is to be noted that each of the present technologies explained herein can be realized independently in so far as any inconsistency does not occur. Needless to say, the present technologies also can be optionally used and realized. For example, part or the entirety of the present technology explained in any one of the embodiments can be realized in combination with part or the entirety of the present technology explained in another one of the embodiments. In addition, part or the entirety of any one of the abovementioned present technologies can be realized in combination with any other technology that is not explained herein.

### Configuration Examples of Electronic Apparatus

The abovementioned imaging element 11 is applicable to a variety of electronic apparatuses including imaging systems such as a digital still camera and a digital video camera, a mobile phone equipped with an imaging function, and any other apparatus equipped with an imaging function, for example.

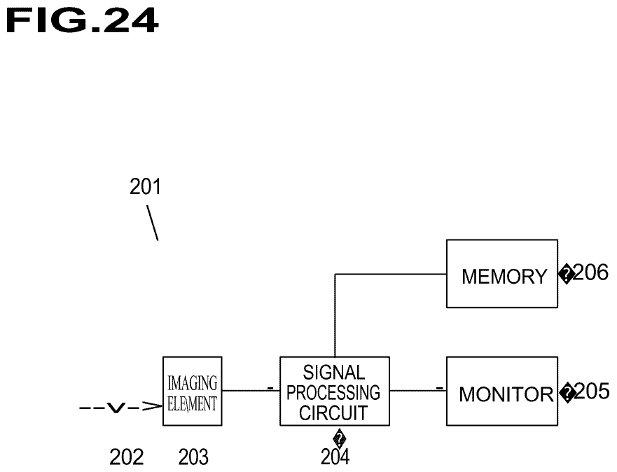

FIG. 24 is a block diagram depicting a configuration example of an imaging apparatus that is installed in an electronic apparatus.

As depicted in FIG. 24, an imaging apparatus 101 includes an optical system 102, an imaging element 103, a signal processing circuit 104, a monitor 105, and a memory 106, and is capable of capturing a still picture and a video.

The optical system 102 includes one or more lenses, and guides image light (incident light) from a subject toward the imaging element 103, and forms an image on a light reception surface (sensor section) of the imaging element 103.

The abovementioned imaging element 11 is applied as the imaging element 103. In the imaging element 103, an electron is stored for a fixed time period according to an image formed on the light reception surface via the optical system 102. Then, a signal corresponding to the electron stored in the imaging element 103 is supplied to the signal processing circuit 104.

The signal processing circuit 104 performs various signal processes on pixel signals outputted from the imaging element 103. An image (image data) resulting from a signal process performed by the signal processing circuit 104 is supplied to the monitor 105 and is displayed thereon, or is supplied to the memory 106 and is stored (recorded) therein.

When the abovementioned imaging element 11 is applied to the imaging apparatus 101 having the abovementioned configuration, a picture with higher image quality can be obtained, for example.

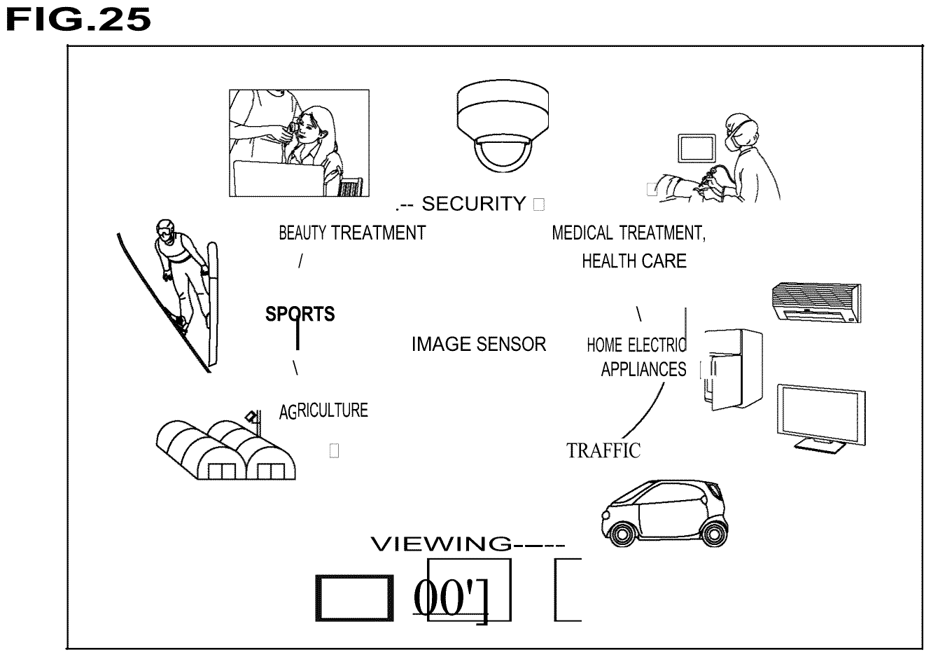

### Usage Examples of Image Sensor FIG. 25 is a diagram depicting usage examples of the abovementioned image sensor (imaging element).

The abovementioned image sensor can be used for a variety of cases of sensing visible light, infrared light, ultraviolet light, X rays, etc., as follows.
An apparatus for photographing images to be viewed, such as a digital camera or a mobile apparatus having a camera function
An apparatus for traffic use, such as an on-vehicle camera for photographing front, rear, and surrounding areas and the interior of an automobile, a monitoring camera for monitoring traveling vehicles and roads, and a ranging sensor for measuring inter-vehicle distances etc. in order to realize safety driving such as automatic stop or to recognize driver conditions, for example
An apparatus for use in a home electrical appliance such as a TV, a refrigerator, or an air conditioner in order to photograph a user gesture and perform an apparats operation according to the gesture
An apparatus for medical treatment and health care, such as an endoscope or an apparatus for angiography using reception of infrared light
An apparatus for security use, such as a crime prevention monitoring camera and a camera for personal authentication
An apparatus for beauty treatment, such as a skin diagnose apparatus for photographing skins and a microscope for photographing scalps
An apparatus for sports use, such as an action camera or a wearable camera for sports applications etc.
An apparatus for agricultural use, such as a camera for monitoring the conditions of fields and crops

### Combination Examples of Configurations

It is to be noted that the present technology can also have the following configurations.

(1)

A semiconductor device including:
a first semiconductor chip;
a second semiconductor chip that is bonded to the first semiconductor chip by CoW (Chip on Wafer) bonding; and
a high-stress film that generates stress to cancel stress to be generated in the first semiconductor chip or the second semiconductor chip during CoW bonding.
   (2)

The semiconductor device according to (1) above, in which
the high-stress film is disposed in an arrangement pattern having high density in regions close to four corners of the first semiconductor chip or the second semiconductor chip and having low density in a region around a center of the first semiconductor chip or the second semiconductor chip.
   (3)

The semiconductor device according to (1) or (2) above, in which
the high-stress film is disposed in an arrangement pattern that is vertically and horizontally symmetrical with respect to a rectangular shape of the first semiconductor chip or the second semiconductor chip.
   (4)

The semiconductor device according to any one of (1) to (3) above, in which,
in a case where contraction stress is applied to the first semiconductor chip during CoW bonding, the high-stress film disposed on the first semiconductor chip generates stress to expand the first semiconductor chip.
   (5)

The semiconductor device according to any one of (1) to (4) above, in which
the high-stress film is disposed in an interior of or on an outermost surface of a wiring layer that is a second-semiconductor-chip bonding surface side of the first semiconductor chip.
   (6)

The semiconductor device according to (5) above, in which a part and another part of the high-stress film are disposed in different layers inside the wiring layer.

(7)

The semiconductor device according to any one of (1) to (6) above, in which,
in a case where the first semiconductor chip and the second semiconductor chip have the same chip size, the high-stress film that has the same size as the first semiconductor chip and the second semiconductor chip is disposed.
   (8)

The semiconductor device according to any one of (1) to (6) above, in which,
in a case where Cow bonding of the second semiconductor chip to the first semiconductor chip that has a larger chip size than the second semiconductor chip is performed, the high-stress film is disposed over an area of the first semiconductor chip wider than the second semiconductor chip.
   (9)

The semiconductor device according to any one of (1) to (6) above, in which,
in a case where CoW bonding of a plurality of the second semiconductor chips to the first semiconductor chip is performed, an area where the high-stress film is disposed on the first semiconductor chip is wider than each of the second semiconductor chips.
   (10)

The semiconductor device according to any one of (1) to (9) above, in which
the high-stress film is disposed so as to cover the second semiconductor chip after CoW bonding of the second semiconductor chip to the first semiconductor chip.
   (11)

The semiconductor device according to any one of (1) to (10) above, in which
the high-stress film includes at least two kinds of materials.
   (12)

The semiconductor device according to (11) above, in which the high-stress film is formed using, for a region where stress to contract the first semiconductor chip or the second semiconductor chip to be generated by Cow bonding is large, a material that has a relatively strong force for canceling stress, and using, for a region where stress to contract the first semiconductor chip or the second semiconductor chip to be generated by CoW bonding is small, a material that has a relatively weak force for canceling stress.

(13)

The semiconductor device according to (11) or (12) above, in which,
in place of the high-stress film, an air gap that releases contraction stress to be generated after CoW bonding is disposed in a region where pressure is applied during Cow bonding.
   (14)

The semiconductor device according to any one of (11) to (13) above, in which
the high-stress films are disposed in both the first semiconductor chip and the second semiconductor chip.
   (15)

A semiconductor device manufacturing method including:
forming a high-stress film that generates stress to cancel stress to be generated in a first semiconductor chip or a second semiconductor chip during CoW (Chip on Wafer) bonding of bonding the second semiconductor chip to the first semiconductor chip.
   (16)

An electronic apparatus including:
a semiconductor device including
   a first semiconductor chip,
   a second semiconductor chip that is bonded to the first semiconductor chip by CoW (Chip on Wafer) bonding, and
   a high-stress film that generates stress to cancel stress to be generated in the first semiconductor chip or the second semiconductor chip during CoW bonding.
      (17)

A Semiconductor Device Including:
a first semiconductor chip;
a second semiconductor chip that is bonded to the first semiconductor chip by CoW (Chip on Wafer) bonding;
a strain adjustment film that restrains influence of unevenness of a surface opposite to a first-semiconductor-chip bonding surface of the second semiconductor chip; and
a support substrate that supports the first semiconductor chip and the second semiconductor chip.
   (18)

The semiconductor device according to (17) above, in which
an uneven surface that, according to an SFOR (Site Front least square Range) value of a surface opposite to the first-semiconductor-chip bonding surface of the second semiconductor chip, negates unevenness of the surface is disposed on the strain adjustment film.
   (19)

The semiconductor device according to (17) or (18) above, in which
the strain adjustment film is formed on a second-semiconductor-chip bonding surface of the support substrate or a surface opposite to the second-semiconductor-chip bonding surface of the support substrate.
   (20)

The semiconductor device according to (17) or (18) above, in which
the strain adjustment film is formed in order to improve a flatness of a support-substrate bonding surface of the second semiconductor chip with respect to an embedding layer that embeds a chip step disposed inside the second semiconductor chip.

It is to be noted that the present embodiments are not limited to the abovementioned embodiments, and various modifications can be made within the scope of the gist of the present disclosure. In addition, the effects described in the present description are just examples, and thus, are not limited, and any other effect may be provided.

### REFERENCE SIGNS LIST

11: Imaging element
12: Logic chip
13: Semiconductor wafer
14: Sensor chip
15: High-stress film
16: Insulation film
21: Semiconductor substrate
22: Wiring layer
31: Interlayer insulation film
32: Wiring
33: Bonding pad

1. A semiconductor device comprising:
a first semiconductor chip;
a second semiconductor chip that is bonded to the first semiconductor chip by CoW (Chip on Wafer) bonding; and
a high-stress film that generates stress to cancel stress to be generated in the first semiconductor chip or the second semiconductor chip during CoW bonding.

2. The semiconductor device according to claim 1, wherein
the high-stress film is disposed in an arrangement pattern having high density in regions close to four corners of the first semiconductor chip or the second semiconductor chip and having low density in a region around a center of the first semiconductor chip or the second semiconductor chip.

3. The semiconductor device according to claim 1, wherein
the high-stress film is disposed in an arrangement pattern that is vertically and horizontally symmetrical with respect to a rectangular shape of the first semiconductor chip or the second semiconductor chip.

4. The semiconductor device according to claim 1, wherein,
in a case where contraction stress is applied to the first semiconductor chip during CoW bonding, the high-stress film disposed on the first semiconductor chip generates stress to expand the first semiconductor chip.

5. The semiconductor device according to claim 1, wherein
the high-stress film is disposed in an interior of or on an outermost surface of a wiring layer that is a second-semiconductor-chip bonding surface side of the first semiconductor chip.

6. The semiconductor device according to claim 5, wherein
a part and another part of the high-stress film are disposed in different layers inside the wiring layer.

7. The semiconductor device according to claim 1, wherein,
in a case where the first semiconductor chip and the second semiconductor chip have a same chip size, the high-stress film that has the same size as the first semiconductor chip and the second semiconductor chip is disposed.

8. The semiconductor device according to claim 1, wherein,
in a case where CoW bonding of the second semiconductor chip to the first semiconductor chip that has a larger chip size than the second semiconductor chip is performed, the high-stress film is disposed over an area of the first semiconductor chip wider than the second semiconductor chip.

9. The semiconductor device according to claim 1, wherein,
in a case where CoW bonding of a plurality of the second semiconductor chips to the first semiconductor chip is performed, an area where the high-stress film is disposed on the first semiconductor chip is wider than each of the second semiconductor chips.

10. The semiconductor device according to claim 1, wherein
the high-stress film is disposed so as to cover the second semiconductor chip after Cow bonding of the second semiconductor chip to the first semiconductor chip.

11. The semiconductor device according to claim 1, wherein
the high-stress film includes at least two kinds of materials.

12. The semiconductor device according to claim 11, wherein
the high-stress film is formed using, for a region where stress to contract the first semiconductor chip or the second semiconductor chip to be generated by Cow bonding is large, a material that has a relatively strong force for canceling stress, and using, for a region where stress to contract the first semiconductor chip or the second semiconductor chip to be generated by CoW bonding is small, a material that has a relatively weak force for canceling stress.

13. The semiconductor device according to claim 11, wherein,
in place of the high-stress film, an air gap that releases contraction stress to be generated after CoW bonding is disposed in a region where pressure is applied during Cow bonding.

14. The semiconductor device according to claim 11, wherein
the high-stress films are disposed in both the first semiconductor chip and the second semiconductor chip.

15. A semiconductor device manufacturing method comprising:
forming a high-stress film that generates stress to cancel stress to be generated in a first semiconductor chip or a second semiconductor chip during CoW (Chip on Wafer) bonding of bonding the second semiconductor chip to the first semiconductor chip.

16. An electronic apparatus comprising:
a semiconductor device including
a first semiconductor chip,
a second semiconductor chip that is bonded to the first semiconductor chip by CoW (Chip on Wafer) bonding, and
a high-stress film that generates stress to cancel stress to be generated in the first semiconductor chip or the second semiconductor chip during Cow bonding.

17. A semiconductor device comprising:
a first semiconductor chip;
a second semiconductor chip that is bonded to the first semiconductor chip by CoW (Chip on Wafer) bonding;
a strain adjustment film that restrains influence of unevenness of a surface opposite to a first-semiconductor-chip bonding surface of the second semiconductor chip; and
a support substrate that supports the first semiconductor chip and the second semiconductor chip.

18. The semiconductor device according to claim 17, wherein
an uneven surface that, according to an SFOR (Site Front least sQuare Range) value of a surface opposite to the first-semiconductor-chip bonding surface of the second semiconductor chip, negates unevenness of the surface is disposed on the strain adjustment film.

19. The semiconductor device according to claim 17, wherein
the strain adjustment film is formed on a second-semiconductor-chip bonding surface of the support substrate or a surface opposite to the second-semiconductor-chip bonding surface of the support substrate.

20. The semiconductor device according to claim 17, wherein
the strain adjustment film is formed in order to improve a flatness of a support-substrate bonding surface of the second semiconductor chip with respect to an embedding layer that embeds a chip step disposed inside the second semiconductor chip.
